(19) United States
(12) Patent Application Publication
(10) Pub. No.: US 2003/0070836 A1
(43) Pub. Date: Apr. 17, 2003

(54) PGA chip package and process for same

(76) Inventors: David W. Quint, Ft. Collins, CO (US); Quan Qi, Fort Collins, CO (US); Karl J. Bois, Ft. Collins, CO (US)

Correspondence Address: HEWLETT-PACKARD COMPANY, Intellectual Property Administration, P. O. Box 272400, Fort Collins, CO, 80527-2400, US

(21) Appl. No.: 10/159,535

(22) Filed: May 31, 2002

Related U.S. Application Data
(62) Division of application No. 09/977,595, filed on Oct. 12, 2001.

(51) Int. Cl. H05K 1/16

(52) U.S. Cl. 174/260

(57) ABSTRACT

The present invention provides a PGA chip package that utilizes a plurality of flexible spring pins. More specifically, the spring pins, while attached between a printed circuit board and any region of the substrate, provide a bent central region that can expand or contract during operational cycles to reduce flaking, cracking, and ultimately an electrical open.

### BACKGROUND OF THE INVENTION

1. Field of the Invention

This invention relates in general to a pin grid array (“PGA”) chip package, and more particularly to a process and assembly for a PGA chip package that can accommodate the temperature changes of a high-speed device and how they translate to the package materials and associated printed circuit board (“PCB”) to dictate the service life of the PGA chip package.

2. Description of the Related Art

In response to current demands from the electronics industry to produce smaller, faster, and more reliable devices, many semiconductor manufacturers have looked at exploiting the advantages of pin grid array (“PGA”) technology. Originally, PGA packages required the associated printed circuit boards (“PCB”) to have through holes so that pins in a PGA package could be wave soldered into the through holes.

With recent developments in surface mount technology (“SMT”), various manufacturers have introduced a surface mountable PGA package to efficiently use the PCB surface area. A straight or quad flat pack (“QFP”) pin is typically used to couple the PGA to the PCB. Unfortunately, these pins have a tendency to fail during operation because of the excessive thermal cycling properties of current chips. More specifically, the differences in the coefficient of thermal expansion (“CTE”) between the ceramic chip package and the fiberglass/ resin printed circuit board (“PCB”) assembly causes excessive strain on the pins at the edges during operational cycles. Consequently, the pins separate when the solder that connects the pins flakes or cracks between the PCB and/or ceramic package to form electrical opens making the package unreliable and ineffective.

To pictorially illustrate the above-mentioned problems, FIGS. 1A and 1B show a cross-sectional and a top plan view of a PGA assembly 9A before being attached to a ceramic substrate 15. These figures show a PGA substrate 15 having contact wires 17 and a straight pin structure 19. Contact wires 17 conventionally mount between the chip contact terminals 11A and the substrate contact terminals 15A (See FIG. 1B). The straight pin structure 19 includes a first end 19A of an array of pins 19 being attached to solder pads 19B on the bottom surface of the substrate 15 to establish a connection with the contact wires 17 through the substrate 15. A protective layer 13, of a material such as an epoxy resin, is deposited to encapsulate the chip 11, the contact wires 17, and a portion of the substrate 15.

As illustrated in FIG. 2, the second ends of pins 19 are attached to the PCB 20. Once the PGA assembly 9B is attached to the PCB 20, the chip can be activated. During operation, the chip 11 will cycle through high and low temperatures, which will in turn strain the resultant structure along every axial plane. Given the size of the PGA assembly 9B, the greatest strain on the pins 19 will occur near a peripheral region 21. As mentioned above, this strain is due to different CTE properties of the assembly. More specifically, the PCB 20 provides a greater CTE change S1 during operation than the CTE change S2 provided by the package. These strains induce the pin joints or ends to flake 19C and crack 19D as illustrated in FIG. 2.

Currently, the chip package of choice for high-speed or signal integrity is the ceramic flip chip, such as an SRAM chip package on a 1 inch ceramic substrate having a PGA structure containing up to 500 straight pins with a pitch of 100 mm. This chip reaches operational temperatures between about 30 and 110 degrees Celsius. Unfortunately, as mentioned above this type of chip package has a tendency to fail during normal temperature cycling because of the significant difference in CTE of its constituent parts. Such cycles create shear and axial related deformations to increase the likelihood of the pins flaking and cracking and decrease the service life of the PGA package.

The magnitude of the strain on the PGA pins that result from operation depends on the geometry of the chip, the temperature difference and the CTE's of the materials involved. The operating temperature of a given chip depends on its function, signal speed and technology. As performance increases, temperatures tend to follow. It is very difficult to keep chips operating at low temperature. The materials can be changed at a price. Exotic board materials with smaller CTE's (closer to ceramics) are available. However, they do not have the track record of success enjoyed by conventional FR-4 board materials. In turn, their electrical properties are so different, that board designs have to be adjusted for them. Given the current focus on keeping costs low, this is an unattractive option.

The present invention is directed to overcoming, or at least reducing the effects of, one or more of the problems set forth above.

### SUMMARY OF THE INVENTION

In one aspect of the present invention, a semiconductor device assembly is provided for reducing the development of electrical opens created during operational cycles. More specifically, the present invention provides a semiconductor chip coupled to a first side of a substrate; and an array of spring pins coupled between a PCB and a second side of the substrate.

In another aspect of the instant invention, a process is provided for coupling a semiconductor chip to a printed circuit board (“PCB”). More specifically, the process includes the steps of securing the chip to a first surface of a substrate; and coupling an array of spring pins between a second surface of the substrate and the PCB.

In still another aspect of the instant invention, a PGA package assembly is provided. More specifically, the present assembly includes a semiconductor chip; a substrate; a printed circuit board (“PCB”); and an array of spring pins coupled between the PCB and the substrate that provide a flexible characteristic for accommodating the physical changes that the resultant structure endures during operational cycles.

### BRIEF DESCRIPTION OF THE DRAWINGS

Other aspects and advantages of the invention will become apparent upon reading the following detailed description and upon reference to the drawings, in which:

FIGS. 1A and 1B illustrate a cross-sectional and a top plan view of a conventional PGA being connected at one end to a chip substrate;

FIG. 2 illustrates a cross-sectional view of the conventional PGA assembly of FIGS. 1A and 1B after being attached to a PCB and activated;

FIGS. 3A and 3B illustrate a cross-sectional and a bottom plan view of the inventive PGA assembly in accordance with one embodiment of the present invention;

FIGS. 4A and 4B illustrates an exploded view of the inventive spring pin structures according to a preferred embodiment of the invention; and

FIG. 5 illustrates a flow chart outlining a basic process for manufacturing any embodiment of the present invention.

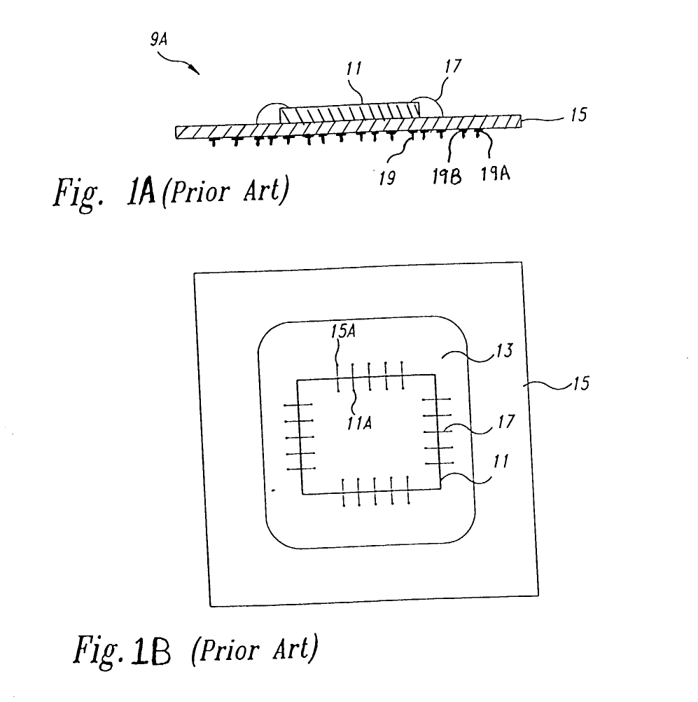

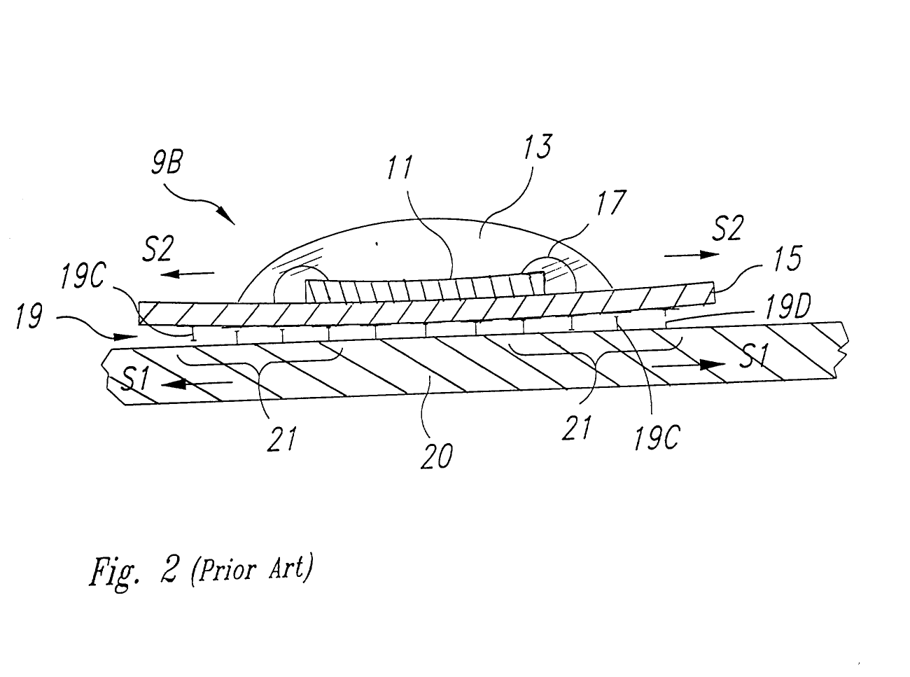

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

In general, the present invention provides a pin grid array (“PGA”) chip package assembly. More specifically, the present invention provides a novel spring type pin design to form a PGA assembly that can: (1) reduce the maximum normal stress in the PGA assembly during operational cycles; (2) potentially extend the service life of a PGA assembly; (3) provide feasibility of assembling a ceramic PGA package onto a laminate printed circuit board (“PCB”) using standard surface mounting technologies (“SMT”); and (4) allow a ceramic PGA package to be assembled onto a laminate PCB using lead-free SMT, thereby replacing lead solder balls. Therefore, the inventive PGA assembly will allow the high-speed pins to remain connected (i.e., minimal flaking and cracking at either pin connection point) between an associated high power chip substrate and a PCB. This is made possible because the novel pins provide a central “V” or “C” shape body section that absorbs or reduces the shear and axial strain incurred during operational cycles that are created by the different thermal expansion properties associated with each material used to manufacture a high speed chip package.

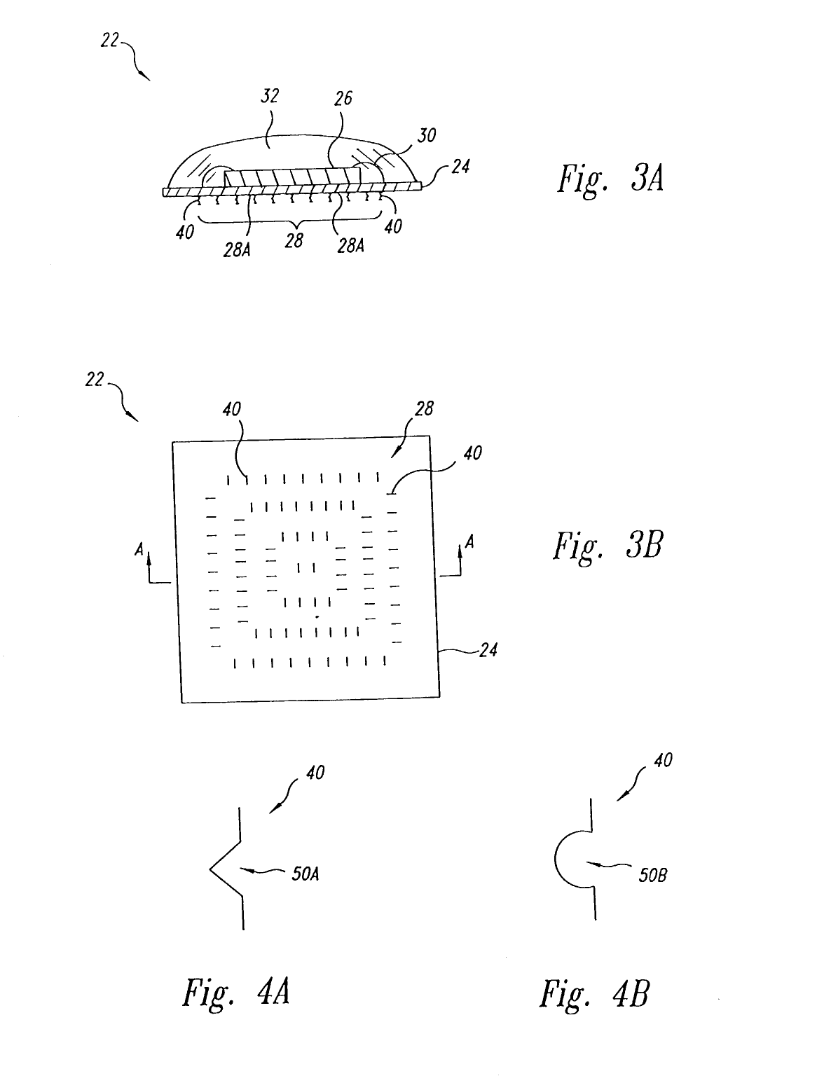

Referring now to the drawings, FIGS. 3A and 3B illustrate an inventive PGA package 22 in accordance with one embodiment of the present invention. More specifically, FIG. 3A shows a cross-sectional view of the package 22 having a substrate 24 conventionally coupled between a semiconductor chip 26 and a set 28 of the inventive spring pins 40. The metallic bond wires 30 and the bottom surface of chip 26 electrically couple the I/O terminals (not shown) of the semiconductor chip 26 to each individual spring pin 40 via the substrate 24. A protective layer 32 of a conventional resin material covers the chip and an adjacent portion of the substrate 24.

The spring pin set 28 includes an array of conductive paste pads 28A coupled between the substrate 24 and the spring pins 40. Depending on the operational characteristics (e.g., cycle temperatures) and structural characteristics (e.g., terminal layout) of the substrate 24, the pitch and number of spring pins for the PGA set 28 may change for any given package. However, for most embodiments of this invention the pitch for the PGA set 28 will define a 4×4 to 50×50 array of spring pins 28 (i.e. between about 16 to 2500 spring pins) for a conventional high-speed and/ or high temperature chip.

In a preferred embodiment, the spring pins 40 are brazed onto the substrate at a first end. The other ends of the pins are soldered to a printed circuit board (“PCB”) (not shown) by conventional methods. As an alternative embodiment, the first ends of the spring pins 40 could be adhesively coupled to the substrate bottom surface or within a contact via using a conductive adhesive by conventional methods. The adhesive material could be an epoxy or an adhesive spray having conductive flakes (e.g., silver, gold, etc.).

In turn, the first end of the spring pins 40 could be staked or embedded to the substrate.

Referring now to FIGS. 4A and 4B, an exploded view of the inventive “C” and “V” spring pins 40 are illustrated. Basically, the inventive spring pins are formed by bending a conventional straight pin in a central region to form a shape similar to a “C” or a “V” as illustrated in FIGS. 4A and 4B. For the purposes of this invention, the bent shape of the inventive spring pins may be created before or after the spring pins are attached to the substrate. The flexible nature of the spring pins as utilized in the PGA set 28 (see FIGS. 3A and 3B) will withstand the expansion and contractions of an active chip.

The spring pin set 28 will allow a manufacturer to trouble shoot any conductivity problems with a chip set before the chip set is physically coupled to a PCB using a conventional method of soldering or the like. More specifically, the pin set is placed in contact with a test socket comprised of an array of conductive pads. The chip set is then pressed to compress the spring pins against the test socket pads to make a low resistance connection. Such a force applied to a conventional straight pin would damage the pin, however the force applied to the inventive spring pins will only flex the spring pins in a predictable manner. The testing can be completed within a few minutes, and the circuit can be removed from the socket and sorted according to its performance in the test. Consequently, if a chip set does not work, it can be discarded before assembly, avoiding the expensive process of repairing and retesting the printed circuit board. Note that it is considerably more difficult to test and diagnose a completed printed circuit board than to test and diagnose a single integrated circuit.

The spring pins structure will provide compatible height and pitch parameters relative to PCB and the requirements of the chip 26 being contained by the substrate 24. For example, the pitch for the spring pins could be between about 30 and 100 mils, and the number of pins could be between about 16 and 2500 pins. However, depending on the number of spring pins 40 necessary to accommodate the I/O terminals of the semiconductor chip 26, the pins 40 may be positioned anywhere on the bottom surface or edge of the substrate 24.

In the particular illustrated embodiments, the conductive spring pins are constructed from a conductive material such as copper alloy. The pins may be plated with gold or tin to help resist corrosion. The substrate 24 is preferably a ceramic substrate such as a FR-4 or a cyanate ester substrate, however, it could be any conventional substrate selected from the group including other tape or plastic (laminate). The metallic bond wires 30 are constructed from a conductive material such as copper, gold, palladium, or aluminum and electrically coupled between the substrate 24 and the spring pins using a known wire bonding technique.

It is an intention of the above embodiments to provide an inventive PGA package that can accommodate any high-speed semiconductor chip, such as a central processing unit (“CPU”), CPU peripheral support, graphic engines, ASIC chips, etc., that can operate at various cycle rates while reaching temperatures of between about 30°-110°. More specifically, if an ASIC chip were conventionally coupled to a one inch square ceramic substrate, it would preferably provide about 576 spring pins brazed to the substrate. In the above example a pitch of 40 mils is used for the spring pins.

Process of Invention

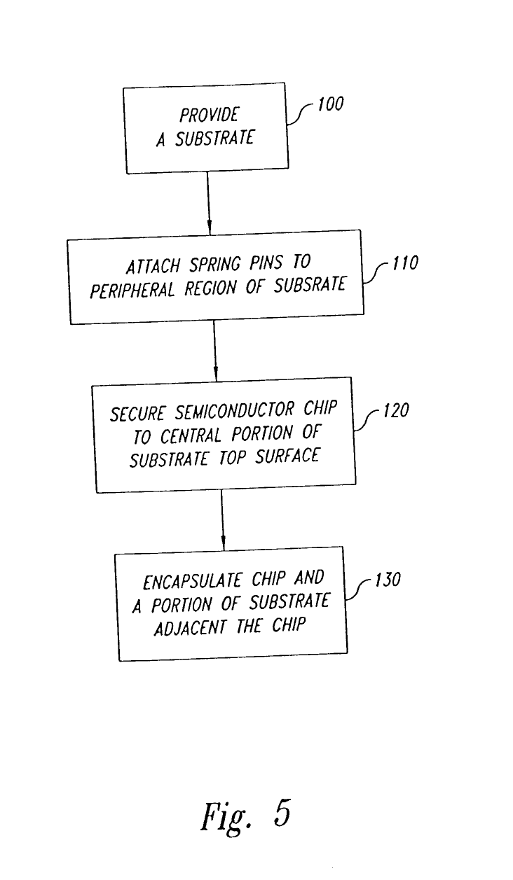

Having described the preferred component layouts for the present invention, a description of the process will now follow. The process is generally illustrated in FIG. 5 and begins by providing a substrate 100. Next, a plurality of spring pins are coupled to the substrate bottom surface 110; a forming process may be used to bend the pins at this time; a semiconductor chip is secured to a central portion of the substrate top surface 120; and the chip and a portion of the substrate is encapsulated 130.

Persons of ordinary skill in the relevant arts should appreciate that the ordering of the process steps, other than providing a substrate and encapsulating the chip after it has been attached, is not material to the practice of the invention

The method of FIG. 5 can be employed to manufacture any of the above embodiments. Consequently, for purposes of clarity the following specific example will describe a process of manufacturing an inventive “C” spring pin chip package with reference to the embodiment of FIGS. 3A and 3B.

Initially, once a substrate 24 is obtained, such as a ceramic or FR-4 substrate, a plurality of spring pins 40 are brazed onto a bottom region of the substrate. Next, the desired semiconductor chip 26 is coupled to the top surface of the substrate 24 and metallic bonding wires 30 are coupled between the semiconductor chip 26 and the substrate 24 using known techniques. At this stage, all I/O terminals of the chip have been coupled to the substrate to interact with the spring pins to be attached.

An encapsulating layer 32 is deposited over the chip 26 and an adjacent portion of the substrate 24. The curing process involves the protective layer 32 shrinking around the semiconductor chip 26 and an adjacent portion of the substrate. Once cured, the resultant package is conventionally soldered to a PCB using the other end of the spring pins.

During the above process, the spring pins may be bent to form the desired “C” or “V” shape before or after being coupled to the PCB.

As an alternative to the above manufacturing process, the manufacturer may decide to test the chip 26 coupled to the substrate before permanently attaching the other end of the spring pins to the PCB. This could be accomplished by aligning the other ends of the spring pins over the desired contact pads of the PCB and applying a force to slightly flex each spring pin and electrically couple the chip to the PCB. With this temporary electrical connection established, all conductivity tests can be performed without ever having to physically connect the other end of the spring pins to the PCB. Therefore, if the chip set is faulty or some other aspect of the manufacturing process for coupling the substrate between the chip and the first end of the spring wires has failed, the process can start over before the other end of the spring pins are attached to the PCB

Summary

As discussed above with reference to the prior art, this inventive assembly does not look to change or alter the CTE properties of the chip package by using different materials or reducing the operational temperature of a chip. Instead, the present invention replaces straight pins of a conventional PGA structure with flexible spring pins to produce a high-speed chip package that will be reliable, effective, and efficient during any operational cycle and temperature. The inventive spring pins will allow for the reduction of the maximum normal stress in PGA pins by using bent pin designs. In addition, the inventive spring pins will allow chip sets to be tested before they are permanently attached to a circuit board substrate, and thereby allowing manufacturers the ability to avoid the current expensive process of repairing and retesting a printed circuit board. Consequently, any temperature applied or cycle rate used with the inventive package that may alter the material integrity of the structure and thereby create a strain within the inventive package coupled to a substrate and pcb will be absorbed by the flexible spring pins and thereby prevent electrical opens. In turn, this will potentially extend the service life of a PGA assembly; provide feasibility of assembling a ceramic PGA package onto a laminate printed circuit board (“PCB”) using standard surface mounting technologies (“SMT”); and allow a ceramic PGA package to be assembled onto a laminate PCB using lead-free SMT, thereby replacing lead solder balls

The particular embodiments disclosed above are illustrative only, as the invention may be modified and practiced in different but equivalent manners apparent to those skilled in the art having the benefit of the teachings herein. Furthermore, no limitations are intended to the details of design herein shown, other than as described in the claims below. It is therefore evident that the particular embodiments disclosed above could be altered or modified and all such variations are considered within the scope and spirit of the invention. Accordingly, the protection sought herein is as set forth in the claims below.

What is claimed is:

1. A semiconductor device assembly, comprising:
a semiconductor chip;
a plurality of spring pins;
a substrate coupled between the chip and the plurality of spring pins; and
a PCB coupled to the plurality of spring pins.

2. The assembly of claim 1, wherein said plurality of spring pins have a central C-shaped region.

3. The assembly of claim 1, wherein said plurality of spring pins have a central V-shaped region.

4. The assembly of claim 1, wherein said plurality of spring pins provide a flexible compliance along an axial direction to prevent electrical opens caused by thermal expansion and contraction of an active assembly.

5. The assembly of claim 1, wherein said plurality of spring pins include a bent central region.

6. The assembly of claim 5, wherein the size of the bent central region can increase or decrease in size to absorb thermal expansion and contraction of an active assembly.

7. The assembly of claim 1, wherein the PCB couples to the spring pins by a force applied from the assembly.

8. The assembly of claim 1, wherein said spring pins change shape to reduce the development of electrical opens while the assembly reacts to operational temperature cycles.

9. The assembly of claim 1, wherein said plurality of spring pins provide a pitch of about 30 mils to 100 mils.

10. The assembly of claim 1, wherein said substrate comprises a material selected from the group including BT laminate, FR-4, cyanate ester, alumina, and glass ceramic.

11. The assembly of claim 1, further including bond wire attached between said chip and said substrate.

12. A process of fabricating a semiconductor device assembly, comprising:
providing a substrate including first and second surfaces;
providing a PCB;
coupling a plurality of spring pins between the PCB and a first side of the substrate; and
securing a semiconductor chip to a second surface of the substrate.

13. The process of claim 12, wherein coupling a plurality of spring pins provides a flexibility to the substrate to reduce the development of electrical opens while the assembly reacts to operational temperature cycles.

14. The process of claim 12, wherein coupling a plurality of spring pins further includes attaching said plurality of spring pins to the substrate by a technique selected from the group comprising brazing, embedding, plating, and adhering.

15. The process of claim 14, wherein adhering a plurality of spring pins further includes adhesively coupling said spring pins to the first surface of said substrate using a material having conductive properties.

16. The process of claim 12, wherein providing the substrate includes providing a substrate comprised of a material selected from the group including tape, plastic, laminate, and ceramic.

17. The process of claim 12, further including bond wire attached between said chip and said substrate.

18. The process of claim 12, wherein the step of coupling the spring pins to the PCB further includes the substrate and PCB applying a force to the spring pins to create an electrical connection between the substrate and the PCB.

19. The process of claim 18 further includes testing the conductivity of the assembly.

20. The process of claim 12, wherein the spring pins are formed by bending a central region of straight pins to form a “C” or “V” shaped region.

21. The process of claim 21, wherein the central region of the straight pins are bent before the spring pins are coupled between the substrate and the PCB.

22. The process of claim 21, wherein the central region of the straight pins are bent after the spring pins are coupled between the substrate and the PCB.

23. A semiconductor device assembly being coupled to a PCB, the assembly comprising:
a substrate;
a semiconductor chip coupled to the substrate; and
a plurality of conductive leads electrically coupled between the assembly and PCB, the leads provide a flexible characteristic for accommodating the physical changes that the resultant structure endures during operational cycles.

24. The assembly of claim 23, wherein said plurality of conductive leads provide a bent central region.

25. The assembly of claim 23, wherein said conductive leads change shape to reduce the development of electrical opens while the assembly reacts to operational temperature cycles.
